(19) United States
(12) Patent Application Publication
(10) Pub. No.: US 2007/0104868 A1
(43) Pub. Date: May 10, 2007

(54) Method and apparatus for manufacturing semiconductor device

(76) Inventor: Sung Rae Kim, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/593,689

(22) Filed: Nov. 6, 2006

(30) Foreign Application Priority Data
Nov. 8, 2005 (KR) 10-2005-0106384

(51) Int. Cl. C23C 16/00

(52) U.S. Cl. 427/255.7; 118/715

(57) ABSTRACT

A method and an apparatus for manufacturing a semiconductor device is provided. The method for manufacturing in a process for forming a polysilicon-metal dielectric on a semiconductor substrate, includes: measuring a flow of a mixing gas for forming a polysilicon-metal dielectric; providing the mixing gas to a location outside a process chamber when the flow of the mixing gas is in a first unstable state; and providing the mixing gas to inside of the process chamber to form the polysilicon-metal dielectric when the flow of the mixing gas is in a second state more stable than the first state. Flows of the respective gases that form the mixing gas are controlled by their respective injection valves, and abnormalities in the flows can be detected. Accordingly, defects caused by non-uniform dopant density in the mixing gas may be prevented.

### RELATED APPLICATION(S)

This application claims the benefit under 35 U.S.C. §119(e) of Korean Patent Application Number 10-2005-0106384 filed Nov. 8, 2005, which is incorporated herein by reference in its entirety.

### FIELD OF THE INVENTION

The present invention relates to a method and an apparatus for manufacturing a semiconductor device, more particularly to a method and an apparatus for manufacturing a semiconductor device which may improve uniformity of a thin film.

### BACKGROUND OF THE INVENTION

In general, an inter-layer dielectric is used in planarizing an upper portion of a semiconductor substrate on which a conductive pattern is formed, and in selectively connecting a lower film and an upper film to each other through a contact.

In a conventional inter-layer dielectric, an insulation film formed of phosphosilicate glass (PSG) film or borophosphosilicate glass (BPSG) film is used as a polysilicon-metal dielectric (PMD), which is an insulation film formed before a formation of a metal wire.

However, in a process for forming the aforementioned PMD layer, when the flow of a mixing gas for forming the PMD layer is non-uniform, the content/density of dopant included in the PMD layer can fluctuate, and defects can occur such as shown in FIG. 1.

FIG. 1 is a photograph showing defects in a semiconductor device formed by a method for manufacturing a semiconductor device according to the related art.

Referring to FIG. 1, it can be seen in the formation region of the contact area (shown circled) that an initial BPSG loss of the PMD layer occurs over a PMD liner oxide film. It is believed that the initial BPSG loss of the PMD layer occurs in an etch process for the formation of the contact or in a washing process performed after the etch process.

Therefore, there is a demand for a method for manufacturing a semiconductor device capable of preventing such defects in the PMD layer from occurring.

### SUMMARY OF THE INVENTION

Accordingly, the present invention is directed to a method and an apparatus for manufacturing a semiconductor device that addresses and/or substantially obviates one or more problems, limitations, and/or disadvantages of the related art.

Accordingly, an object of the present invention is to provide a method for manufacturing a semiconductor device capable of preventing or substantially reducing defects occurring in a thin film.

Another object of the present invention is to provide an apparatus for manufacturing a semiconductor device for performing the method for manufacturing a semiconductor device.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method for manufacturing a semiconductor device comprising: (i) measuring a flow of a mixing gas for forming a polysilicon-metal dielectric in a process for forming the polysilicon-metal dielectric on a semiconductor substrate; (ii) providing the mixing gas to a location outside of a process chamber when the flow of the mixing gas is in a first unstable state; and (iii) providing the mixing gas to an inside of the process chamber to form the polysilicon-metal dielectric when the flow of the mixing gas is in a second state more stable than the first state.

In another aspect of the present invention, there is provided an apparatus for manufacturing a semiconductor device incorporating: gas supply portions including a first gas supply portion for providing a first gas, a second gas supply portion for providing a second gas, and a third gas supply portion for providing a third gas; injection valves including a first injection valve for controlling a flow rate of the first gas, a second injection valve for controlling a flow rate of the second gas, and a third injection valve for controlling a flow rate of the third gas; a main pipe connected to the injection valves for mixing the first, second, and third gases to generate a mixing gas; a main valve at the main pipe for controlling a flow rate of the mixing gas; and a three-way valve connected to the main pipe for providing the mixing gas to an inside of a process chamber or to a location outside of the process chamber.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a photograph showing defects in a semiconductor device formed by a method for manufacturing a semiconductor device according to the related art;

FIG. 2 is a diagram for describing an apparatus and method for manufacturing a semiconductor device according to and embodiment of the present invention;

FIG. 3 is a graph showing Secondary Ion Mass Spectrometry (referred to as ‘SIMS’ hereinafter) data of a device when a flow of a gas passing through an injection valve is normal according to an embodiment of the present invention; and

FIG. 4 is a graph showing SIMS data of a device when an abnormality occurs in the flow of a gas passing through an injection valve according to an embodiment of the present invention.

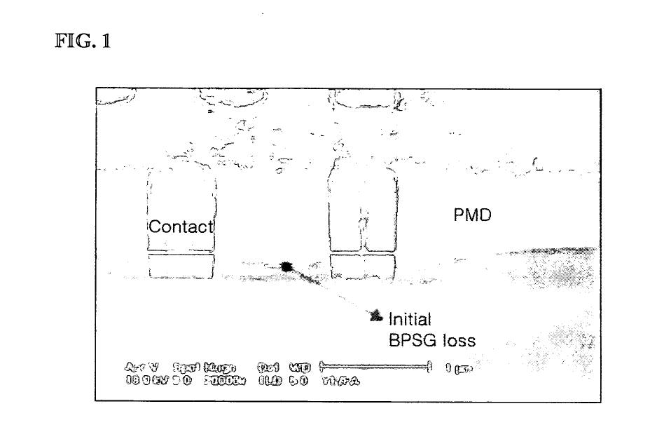

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

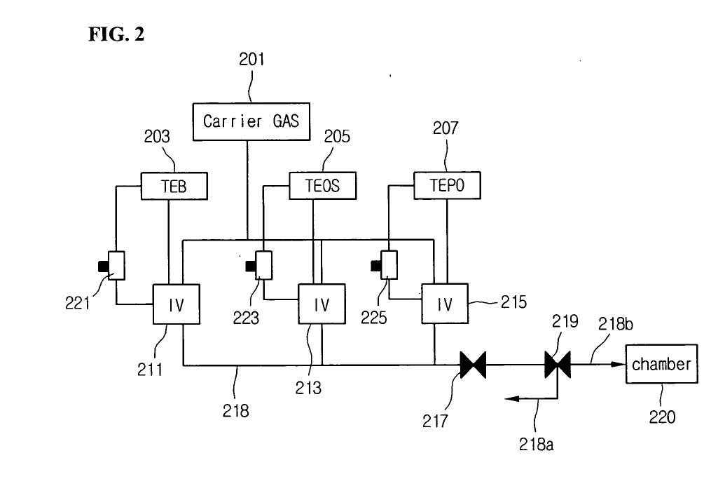

FIG. 2 is a plan view for describing an apparatus and method for manufacturing a semiconductor device according to an embodiment of the present invention.

Referring to FIG. 2, an apparatus for manufacturing a semiconductor device to embody the corresponding method for manufacturing a semiconductor device can include a carrier gas supply portion 201, a first gas supply portion 203, a second gas supply portion 205, and a third gas supply portion 207. In one embodiment, the first gas supply portion 203 can provide TEB (triethylborate) gas, the second gas supply portion 205 can provide TEOS (tetraethylorthosilicate) gas, and the third gas supply portion 207 can provide TEPO (triethylphosphate) gas. The carrier gas supply portion 201 can provide a carrier gas to convey the first gas, second gas, and third gas to the process chamber 220. In a specific embodiment, helium gas or nitrogen gas can be used as the carrier gas.

In a further embodiment, the apparatus can include a first injection valve 211, a second injection valve 213, and a third injection valve 215. The first injection valve 211 can be connected to the first gas supply portion 203. The second injection valve 213 can be connected to the second gas supply portion 205. The third injection valve 215 can be connected to the third gas supply portion 207.

The first injection valve 211, second injection valve 213, and third injection valve 215 can be connected to a main pipe 218. A main valve 217 and 3-way valve 219 can be connected to the main pipe in series after the first, second, and third injection valves 211, 213, and 215.

Two sub pipes 218a and 218b can be connected to the 3-way valve 219 such that sub pipe 218a can be directed away from a process chamber 220 and the sub pipe 218b can connect the main pipe 218 to the process chamber 220 through the 3-way valve 219.

The first injection valve 211 can control a flow (or flow rate) of a first gas supplied from the first gas supply portion 203, the second injection valve 213 can control a flow (or flow rate) of a second gas supplied from the second gas supply portion 205, and the third injection valve 215 can control a flow (or flow rate) of a third gas supplied from the third gas supply portion 205.

The first, second, and third gases supplied to the main pipe 218 by the first injection valve 211, the second injection valve 213, and the third injection valve 215 can be mixed with each other in the main pipe 218 to obtain a mixing gas therein. The flow (or flow rate) of the mixing gas generated in the main pipe 218 can be controlled by the main valve 217 formed at the main pipe 218.

Namely, the first injection valve 211, second injection valve 213, and third injection valve 215 can control the flows (or flow rates) of the first, second, and third gases, respectively, supplied from the first, second and third gas supply portions 203, 205, and 207. The main valve 217 can control a flow (or flow rate) of the mixing gas, which is made of the first, second, and third gases.

The 3-way valve 219 formed at the main pipe 218 can selectively provide the mixing gas to the process chamber 220 or to an exterior thereof.

In a method for manufacturing a semiconductor device using the apparatus for manufacturing the semiconductor device having the construction described above, in forming a polysilicon-metal dielectric (referred to as ‘PMD’ hereinafter) embodiments of the apparatus described above can control a flow (or flow rate) of the mixing gas to form the PMD of phosphosilicate glass (PSG) film or borophosphosilicate glass (BPSG) film.

The method for manufacturing a semiconductor device according to an embodiment of the present invention will be described in detail.

Referring again to FIG. 2, in order to form a polysilicon-metal dielectric (PMD) layer on the semiconductor substrate in which a conductive pattern is formed, a first gas can be provided to the main pipe 218 through the first gas supply portion 203 and the first injection valve 211. Further, a second gas can be provided to the main pipe 218 through the second gas supply portion 205 and the second injection valve 213. In addition, a third gas can be provided to the main pipe 218 through the third gas supply portion 207 and the first injection valve 215. Accordingly, the first, second, and third gases can be mixed in the main pipe 218 to obtain a mixing gas.

To form the PMD layer, for example, the first gas supplied to the first gas supply portion 203 may be TEB gas, the second gas supplied to the second gas supply portion 205 may be TEOS gas, and the third gas supplied to the third gas supply portion 207 may be TEPO gas.

When a mixing gas of the first, second, and third gases is initially introduced into the process chamber 220, a flow (or flow rate) of the mixing gas is very non-uniform. Consequently, if the mixing gas having non-uniform flow is provided to the process chamber, a non-uniform PMD layer would be formed on the semiconductor substrate.

In consideration of this, so as to form a PMD layer on the semiconductor substrate according to embodiments of the subject invention, the mixing gas formed in the main pipe 218 can be provided or bypassed to a location outside of the process chamber until the flow of the mixing gas becomes uniform. Accordingly, in a specific embodiment, the mixing gas formed in the main pipe 218 can be provided to a location outside of the process chamber 220 to stabilize a flow of the mixing gas before providing the mixing gas from the main pipe 218 to the process chamber 220.

As the mixing gas, the flow of which is stabilized before being provided to the process chamber 220, a PMD layer free of detects can be formed.

That is, in the method for manufacturing the semiconductor device according to the present invention, a mixing gas determined to have a stable flow can be provided to the process chamber. This can prevent a content/density of a dopant included in the PMD layer from unstably fluctuating, and thus can lead to a formation of a more uniform PMD layer.

In measuring the uniformity of the flow of the mixing gas of the present invention, a method for detecting whether a flow of the mixing gas is normal or abnormal has been suggested in one embodiment based on a voltage value measured through the first injection valve 211, the second injection valve 213, and the third injection valve 215.

As described above, the apparatus for manufacturing a semiconductor device according to an embodiment of the present invention can include a first injection valve 211, a second injection valve 213, and a third injection valve 215, where the first injection valve 211 can control an amount of TEB gas, the second injection valve 213 can control an amount of the TEOS gas, and the third injection valve 215 can control an amount of TEPO gas. Referring again to FIG. 2, in such an embodiment, a first voltage detector 221, a second voltage detector 223, and a third voltage detector 225 can be connected to the first, second, and third injection valves 211, 213, and 215, respectively.

Voltages detected by the first voltage detector 221, the second voltage detector 223, and the third voltage detector 225 can have different values depending on the flows of the first, second, and third gases controlled by the first, second, and third valves 211, 213, and 215, respectively. For example, when no gas flows through a valve, the voltage detector can detect a voltage of approximately 5 V and when a gas flows normally through a valve, the voltage detector can detect a voltage of approximately 2.5 V. Accordingly, when the first, second, and third gases do not flow through the first, second, and third valves 211, 213, and 215, the first, second, and third voltage detectors 221, 223, and 225 would each detect a voltage of approximately 5V. In addition, when the first, second, and third gases flow normally through the first, second, and third valves 211, 213, and 215, the first, second, and third voltage detectors 221, 223, and 225 would each detect a voltage of approximately 2.5V.

As described above, the flows of the first, second, and third gases can be monitored by measuring the voltages detected by the first, second, and third voltage detectors 221, 223, and 225.

For example, when the first, second, and third voltage detectors 221, 223, and 225 detect a voltage of approximately 5V, it means that the first, second, and third gases are not flowing through the first, second, and third injection valves 211, 213, and 215. In contrast, when the first, second, and third voltage detectors 221, 223, and 225 detect a voltage of approximately 2.5V, it means that the first, second, and third gases are flowing normally through the first, second, and third injection valves 211, 213, and 215. Furthermore, when the one or more of the first, second, and third voltage detectors 221, 223, and 225 detect a voltage of approximately 1.3V, it means that the one or more of the first, second, and third gases are flowing in an unstable over-flow through the corresponding first, second, and/or third injection valves 211, 213, and 215.

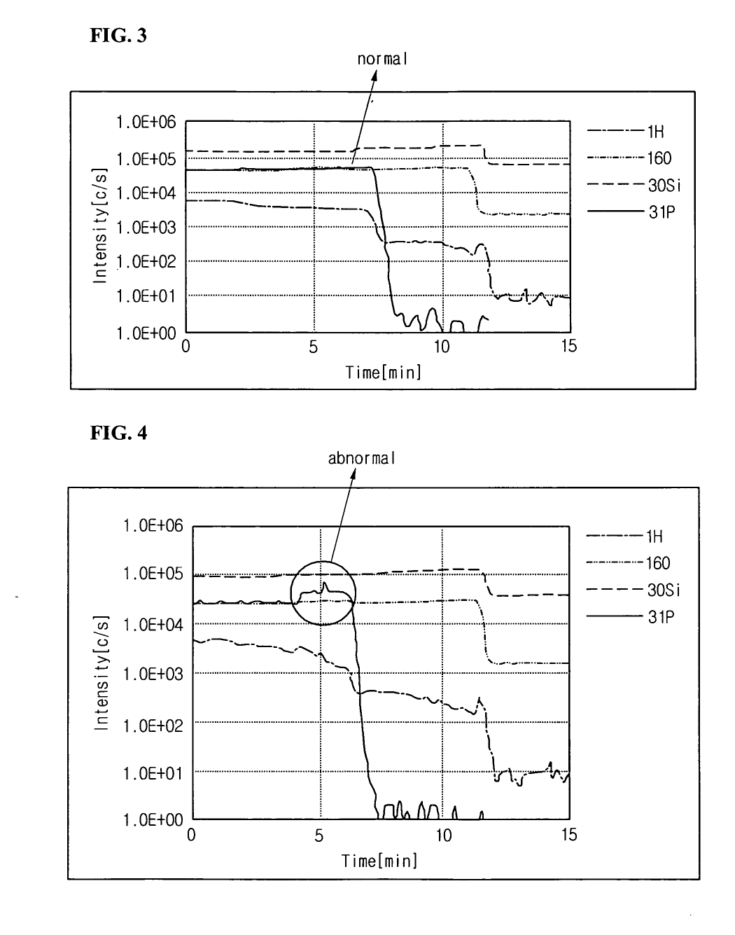

FIG. 3 shows SIMS data when a gas is flowing normally (detection of 2.5V). FIG. 4 shows SIMS data when the gas is flowing in an abnormal state of unstable over flow.

As shown in FIG. 3, when a voltage value of 2.5 V is detected from an injection valve, a normal wave appears. However, as shown in FIG. 4, in a case of an over-flow where a voltage value of 1.3 V is detected from an injection valve, an abnormal wave appears.

As mentioned previously, it can be determined whether a gas flowing through the first injection valve 211, the second injection valve 213, and/or the third injection valve 215 is in a normal/abnormal state based on the voltages measured by the first voltage detector 221, the second voltage detector 223, and the third voltage detector 225.

Therefore, it can be determined whether a flow of a gas is in a normal/abnormal state by monitoring respective voltage values detected by the first voltage detector 221, the second voltage detector 223, and the third voltage detector 225, which allows an abnormal flow of the mixing gas to be detected early.

As is clear from the forgoing description, in the method for manufacturing a semiconductor device according to embodiments of the present invention, in forming a PMD layer, the method may prevent defects due to changes of dopant density from occurring.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method for manufacturing a semiconductor device comprising:
(i) measuring a flow of a mixing gas for forming a polysilicon-metal dielectric on a semiconductor substrate;
(ii) providing the mixing gas to a location outside of a process chamber when the flow of the mixing gas is in an unstable first state; and
(iii) providing the mixing gas to the process chamber to form the polysilicon-metal dielectric when the flow of the mixing gas is in a second state more stable than the first state.

2. The method according to claim 1, wherein the mixing gas for forming a polysilicon-metal dielectric comprises at least one of TEOS (tetraethylorthosilicate), TEPO (triethylphosphate), and TEB (triethylborate).

3. The method according to claim 1, wherein the mixing gas is provided to a location outside the process chamber or to an inside of the process chamber using a 3-way valve.

4. The method according to claim 1, wherein measuring a flow of mixing gas comprises:
measuring a voltage corresponding to a flow rate of a gas passing through an injection valve to be mixed as part of the mixing gas; and
comparing the measured voltage with a reference voltage to determine if the mixing gas is in the first state or the second state.

5. The method according to claim 4, wherein the first state is a measured voltage of 1.3 V and the second state is a measured voltage of 2.5 V.

6. An apparatus for manufacturing a semiconductor device comprising:
a first gas supply portion for providing a first gas, a second gas supply portion for providing a second gas, and a third gas supply portion for providing a third gas;
a first injection valve for controlling a flow rate of the first gas, a second injection valve for controlling a flow rate of the second gas, and a third injection valve for controlling a flow rate of the third gas;
a main pipe connected to the first injection valve, the second injection valve, and the third injection valve for mixing the first, second, and third gases to generate a mixing gas;
a main valve formed at the main pipe for controlling a flow rate of the mixing gas; and
a three-way valve connected to the main pipe for selectively providing the mixing gas to an inside of a process chamber or to a location outside of the process chamber.

7. The apparatus according to claim 6, wherein the first injection valve has a first signal detector for generating an electric signal corresponding to a flow rate of the first gas, the second injection valve has a second signal detector for generating an electric signal corresponding to a flow rate of the second gas, and the third injection valve has a third signal detector for generating an electric signal corresponding to a flow rate of the third gas.

8. The apparatus according to claim 7, wherein the electric signal is a voltage.

9. The apparatus according to claim 6, wherein the first gas is TEB gas, the second gas is TEOS gas, and the third gas is TEPO gas.

10. The apparatus according to claim 6, further comprising a carrier gas supply portion for providing a carrier gas for the first, second, and third gases.

11. The apparatus according to claim 10, wherein the carrier gas is nitrogen gas or helium gas.
